(19) United States
(12) Patent Application Publication
(10) Pub. No.: US 2006/0086458 A1
(43) Pub. Date: Apr. 27, 2006

(54) Ceramic materials in plasma tool environments

(76) Inventors: Hong Jin Kim, Singapore (SG); Joon Myung Kim, Singapore (SG); Rizal Billones Laoreno, Singapore (SG); Kenneth Kok Hong Yue, Singapore (SG)

Correspondence Address: HARNESS, DICKEY, & PIERCE, P.L.C, 7700 BONHOMME, STE 400, ST. LOUIS, MO, 63105, US

(21) Appl. No.: 10/972,911

(22) Filed: Oct. 25, 2004

(51) Int. Cl. H01L 21/306; C23C 16/00

(52) U.S. Cl. 156/345.1; 156/916; 118/715; 118/723 R

(57) ABSTRACT

A liner for the plasma chamber of a plasma tool is described wherein the liner is composed substantially entirely of pure ceramic. A method for preparing such a liner is also described.

### FIELD OF THE INVENTION

The present invention relates to the use of high purity ceramics in plasma tool environments. More particularly but not exclusively it relates to plasma linings or liners for use in the plasma chambers of plasma tools.

### BACKGROUND TO THE INVENTION

The invention relates to the area of plasma tools. Plasma tools generally include plasma etching and deposition devices.

Etching is a technique used frequently in the semiconductor fabrication industry for example. The technique generally can be divided into two groups—wet etching wherein a wet chemical solution is employed to etch a substrate, and dry or plasma etching wherein the etching is effected by a plasma The current invention relates to the field of dry or plasma etching.

Plasma deposition tools include those employed in chemical vapour deposition and physical vapour deposition for example.

In all cases the plasma contains reactive ions which are accelerated towards the substrate or target with an electric field.

Plasma etch devices for example require an etching chamber where the subject of the etching process is mounted and where the etching process takes place. Typically such chambers are made of aluminium or aluminium alloys and may include componentry which are also of aluminium or aluminium alloys. However, problems occur with such aluminium-based componentry as a result of continual exposure to the harsh plasma environment. Gradual erosion of the chamber and components may occur which will lead to the need for replacement and consequently down time for the apparatus.

One solution has been to coat the aluminium components within the chamber with firstly a layer of dielectric material, then a metal barrier layer as disclosed in U.S. patent application publication U.S. 2003/0180556 (Lynn).

Other solutions have included the use of chamber liners in which there is a liner insert of aluminium or aluminium alloy which fits inside the actual etching chamber. In some instances such chambers have been provided with a coating on their inner surface of ceramic material such as alumina Such liners exist in the LAM (London, Australia, Malaysia) 9600PTX plasma etcher for example. The ceramic coating provides an improved, more resistant surface inside the chamber however a number of disadvantages do exist with such a design. The ceramic coating is typically quite thin and after exposure to the conditions within the plasma chamber tends to become brittle causing erosion, cracking and breakdown of the ceramic lining. The ceramic component of the lining is also a victim of thermal expansion relative to the aluminium/aluminium alloy substrate of the lining which adds to the cracking process. Particles of the liner can fall on to the wafer contaminating it and upsetting its balance within the chamber.

One quantitative measurement of this process is in the use of backside helium (or other inert gas). Backside gas is admitted to a plasma chamber to allow (amongst other things) heat transfer between the sample wafer and an electrostatic chuck in the chamber. The electrostatic nature of the chuck is responsible for the relative positioning of the wafer.

When the electrostatic chuck (e-chuck) is contaminated by particles from the cracked liner or other impurities which form as by-products of the process gas, backside helium leak rate will be increased due to uneven chucking forces and this can give rise to helium leak faults which can have a detrimental effect on this wafer.

### OBJECT OF THE INVENTION

It is an object of the present invention to provide a plasma etching and/or deposition environment which overcomes or at least ameliorates some of the abovementioned disadvantages or which at least provides the public with a useful choice.

Other objects of the invention may become apparent from the following description which is given by way of example only.

### SUMMARY OF THE INVENTION

In one aspect of the invention there is provided a liner for a plasma chamber of a plasma tool wherein the liner is made substantially entirely of a ceramic material.

Preferably at least a portion of the surface of the liner has been subject to a surface treatment process to control the surface roughness.

Preferably the surface roughness is in the range 100-180 μinch. More preferably the surface roughness is in the range 120-160 μinch.

Preferably the edges and/or comers of the liner is/are subject to a rounding treatment.

Preferably the rounding treatment is a radiusing treatment. Preferably the radius of the edges and/or comers is in the range 1.5 mm≦d ≦9 mm.

Preferably the liner possesses an interior surface and an exterior surface and that treated portion of the surface is on the interior surface of the liner.

Preferably the treated portion of the surface is substantially the entire interior surface of the liner.

Preferably the ceramic material is of purity >90%. More preferably the ceramic material is of purity >98%; even more preferably it is of purity >99%.

Preferably the ceramic material is selected from a ceramic oxide, more preferably it is selected from zirconia or alumina.

Preferably the liner is a unitary body. Alternatively the liner may be prepared from a plurality of liner sections which are assembled or fitted together.

According to a second aspect of the invention there is provided a liner section substantially as described above.

According to a third aspect of the invention there is provided a plasma chamber of a plasma tool including or fitted with a liner substantially as described above.

According to a further aspect of the invention there is provided a method for preparing a liner for the plasma chamber of a plasma tool comprising or including the steps of:
i) forming or shaping a ceramic liner to a form or shape adapted to be housed within a plasma chamber, and
ii) surface treating the ceramic liner,
wherein the ceramic liner is composed substantially entirely of ceramic.

Preferably the step of surface treating the ceramic liner comprises or includes one or both of:
(a) modification of the surface roughness of at least a part of the ceramic liner, and/or
(b) rounding at least one edge of the ceramic liner.

Preferably the modification of the surface roughness will result in a roughness in the range 100-180 μinch. More preferably the surface roughness is in the range 120-160 μinch.

Preferably the liner possesses an interior surface and an exterior surface and that treated portion of the surface is on the interior surface of the liner.

Preferably the treated portion of the surface is substantially the entire interior surface of the liner.

Preferably the rounding of at least one edge of the ceramic liner is a radiusing treatment. Preferably the radius of the edges and/or corners is in the range 1.5 mm≦d≦9 mm.

Preferably the step of surface treating the ceramic liner comprises both steps (a) and (b). More preferably (a) and (b) are both accomplished via a single process.

Preferably the step of i) forming or shaping a ceramic liner to a form or shape adapted to be housed within a plasma chamber comprises or includes the steps of:
A. formation of a suitable mould,
B. preparation of a mixture of ceramic powder with at least a binder,
C. transferring the mixture into the mould,
D. heating to a process temperature,
E. sintering of the ceramic,
F. removal from the mould.

Preferably the ceramic is a ceramic oxide; more preferably it is selected from zirconia or alumina.

Preferably the ceramic liner is >90% pure ceramic; More preferably it is >98% pure ceramic; even more preferably it is of purity >99% ceramic.

According to a further aspect of the invention there is provided a liner for the plasma chamber of a plasma tool prepared according to the above method.

According to a further aspect of the invention there is provided a liner substantially as herein described and with reference to any one or more the accompanying drawings and/or examples.

Other aspects of the invention may become apparent from the following description which is given by way of example only and with reference to the accompanying drawings.

Definitions

Plasma tool by plasma tool we mean any device in which a plasma chamber is employed within which plasma is used as an agent. This includes plasma etching tools as well as plasma deposition tools, such as in chemical vapour deposition and physical vapour deposition.

### BRIEF DESCRIPTION OF THE DRAWINGS

The invention will now be described by way of example only and with reference to the drawings in which:

FIG. 1: is a schematic view of a the components of a prior art plasma etching device,

FIG. 2: is a schematic view of a plasma etching device which incorporates a chamber liner;

FIG. 3: is a schematic view of the chamber liner of the invention

FIG. 4: is a schematic view of the chamber liner of the invention in the partially assembled chamber;

FIG. 5: is a schematic representation of the surface treatment of the ceramic;

FIG. 6: is an illustration of the edge rounding process.

### DETAILED DESCRIPTION OF THE INVENTION

The present invention relates to an inventive and novel chamber liner for use inside the plasma chamber of a plasma tool such as a plasma etcher or plasma deposition tool (including chemical vapour depositions or physical vapour deposition tool). The invention is appropriate to all such tools as would be envisaged by one skilled in the art including low, medium and high density tools.

The novelty resides in the use of a chamber liner which is entirely composed of a ceramic material. The ceramic may be selected from a ceramic oxide particularly zirconia or alumina, however the preferred ceramic is alumina. In the preferred embodiment the alumina is high purity alumina, ideally 99.8% impurity.

The advantages of using high purity alumina are that the ceramic is more stable in the presence of the plasma. In particular the presence of impurities (such as ceramic binders) increase the brittleness of the ceramic making it more resistant to erosion and cracking.

It will be envisaged by one skilled in the art that there may be situations wherein the liner is attached to or includes certain componentry, fittings or similar when such componentry or fittings may be useful in attachment to the plasma chamber or for locating within or removal from the plasma chamber for example. Such componentry or fittings do not constitute a part of the active chamber liner and as such do not detract from its description as entirely made of ceramic material.

Furthermore, the alumina liner is treated to control the roughness of the surface. This treatment is discussed in greater detail below.

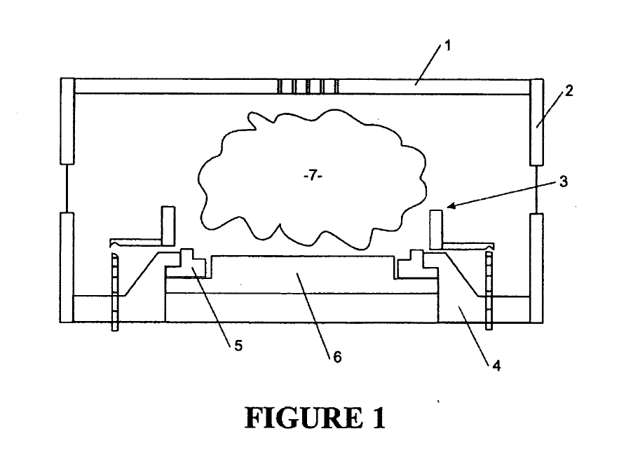

With reference to FIG. I there is illustrated a general schematic of a prior art plasma etching device showing the principal components and including the plasma chamber. The standard components of the casement 1, plasma chamber wall 2, u-ring 3, ground ring 4, edge ring 5 and electrostatic chuck, and the plasma 7 are illustrated in FIG. 1. In this figure no plasma liner is employed.

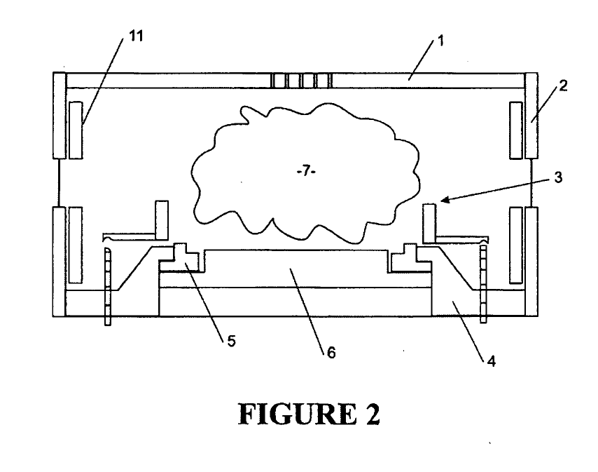

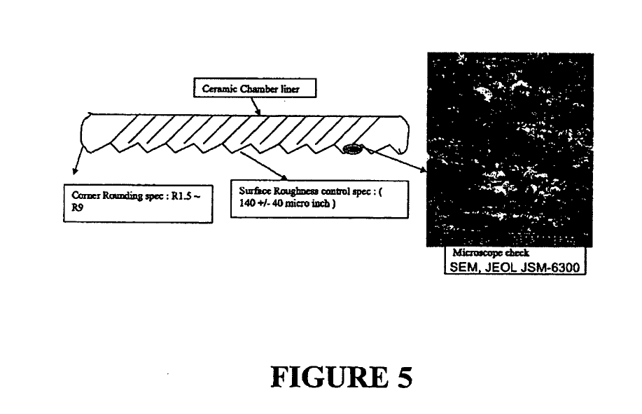

With reference to FIG. 2 there is illustrated a plasma etching device which includes a chamber liner 11 within the plasma chamber. In this case the FIG. 5 is suitable illustration of a prior art etching device such as the LAM 9600 PTX etcher in which the liner 11 is of aluminium with a ceramic coating or it is also appropriate for the current invention where the chamber liner 11 is of substantially pure ceramic.

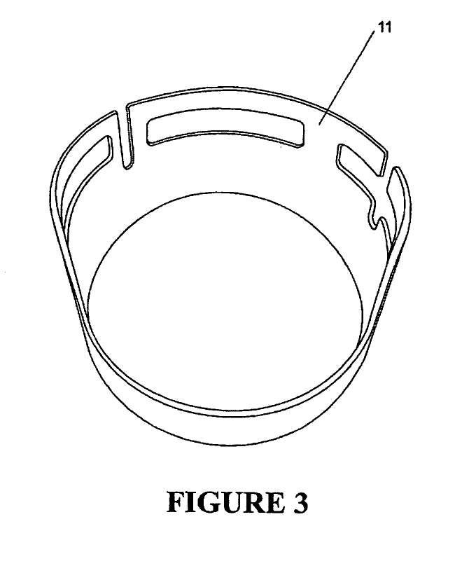

FIG. 3 illustrates the chamber liner 11 of the invention. The larger cut-away portion faces the pumping port whilst the small cut-away areas interact with the u-ring 3.

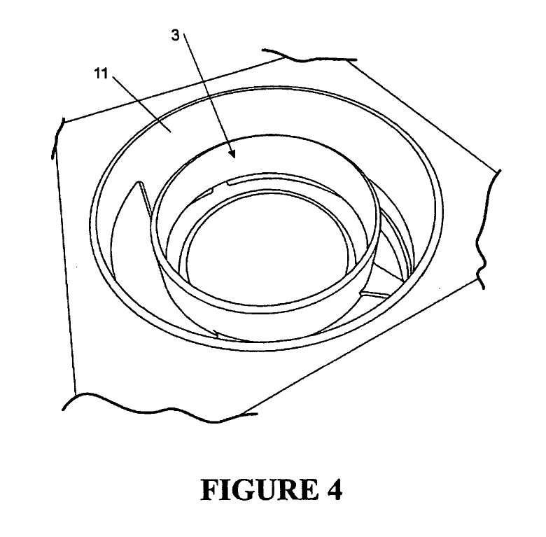

FIG. 4 illustrates the plasma liner of FIG. 3 in position with the u-ring 3. FIG. 4 illustrates an integral, one piece, liner which is the preferred form of invention however, it would be envisaged by one skilled in the art that the chamber liner of the invention could be composed of two or more interfitting components which fit together to make up the chamber liner.

Preparation of the Liner

The simple process steps of preparation of the liner are as follows:
1) a mould is prepared (which can be of plaster or other suitable material);
2) the ceramic powder and binder are mixed in quantities appropriate to provide the high purity ceramic product;
3) the ceramic mixture is poured into the mould and baked at a high temperature. This causes the ceramic to sinter.
4) The ceramic is cooled and then removed from the mould.
5) It is finally subject to surface treatment and rounding as discussed below.

A typical quantity of final ceramic with binder might be 99.8% ceramic and 0.2% binder and other impurities.

Surface Treatment of the Ceramic

FIG. 5 illustrates schematically the nature of the surface once it has been subject to a surface roughness control process and also edge/comer rounding.

The surface is treated essentially by an abrasion process to modify the surface roughness into the range 140±40 μinch. We have found it is important to keep the surface within this range. One of the important properties of the ceramic liner of the invention is its ability to minimise any contamination of the wafer. A by-product of the plasma process is the reaction of the plasma gases to form a polymer which will stick to the ceramic liner. If the surface is too smooth (<100 μinch) then the polymer can't properly stick to the surface whilst If the surface is too rough (>180 μinch) then the polymer again cannot stick as the surface to too brittle. If the polymer has difficulty sticking to the surface particles can fall away onto the wafer.

As will be envisaged by one skilled in the art, any possible surface treatment which brings the roughness into the range 140±40 μinch and does not detrimentally contaminate the surface will be suitable. The preferred surface treatment employs a slurry of silicon carbide powder in deionised water. The typical silicon carbide grain size is 40 mesh. This slurry is prepared and sprayed onto the surface, in the preferred embodiment at a pressure of 0.6 psi. The slurry is then cleaned from the surface with deionised water. This washing process is very effective leaving no significant contamination of the ceramic surface.

After washing the surface roughness is checked using a scanning electron microscope as illustrated in FIG. 5.

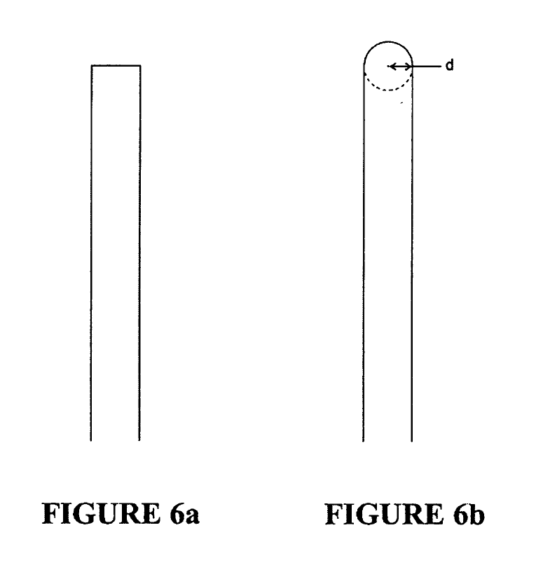

A further important part of the surface treatment is the rounding of the edges of the ceramic liner. After the ceramic liner is formed the edges can be sharp. These edges are more susceptible to erosion and cracking in the hostile plasma enviromnent. Thus we have found it preferable to subject the liner, and particularly the edges to a rounding process. More particularly the edges are radiused to a substantially constant radius (d) selected to be between 1.5 mm and 9 mm. This rounding/radiusing process is illustrated in FIG. 6. FIG. 6a shows an edge prior to rounding treatment whilst FIG. 6b shows the edge after treatment, radiused to radius d. As would be envisaged by one skilled in the art, there are a number of processes which could be used to achieve the edge rounding. We have found it convenient to carry out the rounding as part of the abovementioned surface treatment. In other words the use of the silicon carbide slurry on the surface of the ceramic also achieves the edge rounding. If the degree of rounding/radiusing is not sufficient via this process we can further modify the edges to achieve the required rounding or radius.

Advantages of the use of the Ceramic Liner of the Invention

We have found a number of advantages of use of the ceramic liner of the invention over the prior art—particularly when a liner composed of both aluminium/aluminium alloy and ceramic is used. The essence of these advantages is to minimise contamination of the wafer by polymer by-product and by eroded liner or other contaminant particles. A longer on-line time is achieved and a reduced need for down time. The following advantages are relative to the use of the ceramic and aluminium chamber liner of the LAM (London, Australia, Malaysia) 9600PTX plasma etcher discussed previously. These include:

Minimisation of chamber downtime. The chambers of prior art devices often requires repair and cleaning, resulting in downtime. We have found that the chamber liner of the present invention increases chamber uptime by 2-3% over the LAM 9600PTX plasma etcher.

Inline defect excursion has been minimised. Inline defect excursion essentially describes the result of contaminants dropping onto the wafer thereby causing shorting circuiting or other defects.

Metal extra pattern (MEP) has shown a 0.25 ea/layer reduction over the LAM 9600PTX plasma etcher. MEP again essentially relates to the presence of contaminant metal on the wafer.

Equipment down memo (EDM) of >60% decrease over the LAM 9600PTX plasma etcher, particularly related to backside helium. When the liner of the prior art deteriorates under the plasma conditions then cracking occurs resulting in backside helium leakage and imbalance of the wafer. We have found this to be considerably reduced in the current invention.

A significant cost saving per year for each chamber. As mentioned previously there is a significant polymer by-product issue in chambers of this sort. Further, in chemical vapour deposition for example, deposited film is sputtered off the wafer towards the walls. As a result the chamber or liner inevitably has a significant degree of deposition on the interior surfaces. If this unwanted deposited film should spall off as flakes as a result of thermal expansion, stress or abrasion, particles are generated which will fall onto the wafers. Thus periodic cleaning of the chamber walls is important but results in chamber down time and limits the life of the liner. We have found that the chamber liner of the LAM 9600PTX plasma etcher could effectively operate for 2 runs of 140±20 rf hours (with cleaning between the runs) after which cracking occurs. At best we are able to obtain 400 rf hours total. With the chamber liner of the invention we have managed 1000 rf hours total, with each run (between cleans) lasting approximately 200 rf hours.

Experimental

An example of preparation of a ceramic liner of the invention is as follows:
(a) a plaster mould is prepared suitable for preparing a liner which will fit inside the LAM 9600PTX plasma etcher device
(b) ceramic powder and binder are mixed as follows:
   AL₂O₃ (99.8% by wgt),
   SiO₂ (0.02% by wgt),
   Fe₂O₃ (0.01% by wgt),
   Na₂O (0.06% by wgt),
   Binder: MgO & CaO (0.11% by wgt)
(c) the ceramic mixtures is poured into the mould and baked at approximately 1700° C. for around 7 days.
(d) The final ceramic is then cooled and removed from the mould.
(e) The liner is then subject to the surface roughness treatment and rounding processes using a silicon carbide slurry (40 mesh powder in deionised water) described previously. The slurry is sprayed onto the surface at approximately 0.6 psi, and the surface finally washed with deionised water.

Where in the foregoing description reference has been made to elements or integers having known equivalents, then such equivalents are included as if they were individually set forth.

Although the invention has been described by way of example and with reference to particular embodiments, it is to be understood that modifications and/or improvements may be made without departing from the scope or spirit of the invention.

In addition, where features or aspects of the invention are described in terms of Markush groups, those skilled in the art will Tecognise that the invention is also thereby described in terms of any individual member or subgroup of members of the Markush group.

1. A liner for a plasma chamber of a plasma tool wherein the liner is made substantially entirely of a ceramic material.

2. A liner as claimed in claim 1 wherein at least a portion of the surface of the liner has been subject to a surface treatment process to control the surface roughness.

3. A liner as claimed in claim 2 wherein the surface roughness is in the range 100-180 μinch.

4. A method as claimed in claim 3 wherein the surface roughness is in the range 120-160 μinch.

5. A liner as claimed in claim 1 wherein the edges and/or comers of the liner is/are subject to a rounding treatment.

6. A liner as claimed in claim 5 wherein the rounding treatment is a radiusing treatment wherein the radius (d) of the edges and/or comers is in the range 1.5 mm≦d ≦9 mm.

7. A liner as claimed in claim 6 wherein the liner possesses an interior surface and an exterior surface and that treated portion of the surface is on the interior surface of the liner.

8. A liner as claimed in claim 7 wherein the treated portion of the surface is substantially the entire interior surface of the liner.

9. A liner as claimed in claim 1 wherein the ceramic material is of purity >90%.

10. A liner as claimed in claim 9 wherein the ceramic material is of purity >98%.

11. A liner as claimed in claim 10 wherein the ceramic material is of purity >99%.

12. A liner as claimed in claim 1 wherein the ceramic material is selected from a ceramic oxide.

13. A liner as claimed in claim 12 wherein the ceramic material is selected from zirconia or alumina.

14. A liner as claimed in claim 1 wherein the liner is a unitary body.

15. A liner as claimed in claim 1 wherein the liner is prepared from a plurality of liner sections which are assembled or fitted together.

16. A liner section substantially as described in claim 15.

17. A plasma chamber of a plasma tool including or fitted with a liner the liner substantially as claimed in any one of claims 1 to 15.

18. A method for preparing a liner for the plasma chamber of a plasma tool comprising or including the steps of:
i) forming or shaping a ceramic liner to a form or shape adapted to be housed within a plasma chamber, and
ii) surface treating the ceramic liner,
wherein the ceramic liner is composed substantially entirely of ceramic.

19. A method as claimed in claim 18 wherein the step of surface treating the ceramic liner comprises or includes one or both of:
(a) modification of the surface roughness of at least a part of the ceramic liner, and/or
(b) rounding at least one edge of the ceramic liner.

20. A method as claimed in claim 19 wherein the modification of the surface roughness will result in a roughness in the range 100-180 μinch.

21. A method as claimed in claim 20 wherein the modification of the surface roughness will result in a roughness in the range 120-60 μinch.

22. A method as claimed in claim 21 wherein the liner possesses an interior surface and an exterior surface and that treated portion of the surface is on the interior surface of the liner.

23. A method as claimed in claim 22 wherein the treated portion of the surface is substantially the entire interior surface of the liner.

24. A method as claimed in claim 19 wherein the rounding of at least one edge of the ceramic liner is a radiusing treatment wherein the radius of the edges and/or corners is in the range 1.5 mm≦d≦9 mm.

25. A method as claimed in claim 19 wherein the step of surface treating the ceramic liner comprises both steps (a) and (b).

26. A method as claimed in claim 25 wherein steps (a) and (b) are both accomplished via a single process.

27. A method as claimed in claim 18 wherein the step of i) forming or shaping a ceramic liner to a form or shape adapted to be housed within a plasma chamber comprises or includes the steps of:
A. formation of a suitable mould,
B. preparation of a mixture of ceramic powder with at least a binder,
C. transferring the mixture into the mould,
D. heating to a process temperature,
E. sintering of the ceramic,
F. removal from the mould.

28. A method as claimed in claim 18 wherein the ceramic is a ceramic oxide.

29. A method as claimed in claim 28 wherein the ceramic oxide is selected from zirconia or alumina

30. A method as claimed in claim 29 wherein the ceramic liner is >90% pure ceramic.

31. A method as claimed in claim 30 wherein the ceramic liner is >98% pure ceramic.

32. A method as claimed in claim 31 wherein the ceramic liner is of purity >99% ceramic.

33. A liner for the plasma chamber of a plasma tool prepared according to the method claimed in any one of claims 18 to 32.
